(19) United States
(12) Patent Application Publication
(10) Pub. No.: US 2026/0164794 A1
(43) Pub. Date: Jun. 11, 2026

(54) DISPLAY SUBSTRATE, MANUFACTURING METHOD THEREFOR, AND DISPLAY DEVICE

(71) Applicant: BOE Technology Group Co., Ltd., Beijing (CN)

(72) Inventors: Meng ZHAO, Beijing (CN); Chaolu WANG, Beijing (CN); Jinqian WANG, Beijing (CN)

(21) Appl. No.: 18/705,574

(22) PCT Filed: Apr. 21, 2023
(86) PCT No.: PCT/CN2023/089941

§ 371 Date: Apr. 28, 2024

(30) Foreign Application Priority Data
Jun. 13, 2022 (CN) 202210661034.X

(51) Int. Cl. H10D 86/40; H10D 86/01; H10D 86/60

(52) U.S. Cl. CPC H10D 86/423; H10D 86/0223; H10D 86/481; H10D 86/60

(57) ABSTRACT

A display substrate, a manufacturing method therefor, and a display device are disclosed. The display substrate includes: a base substrate and a plurality of sub-pixels arranged in an array on the base substrate. Each of the sub-pixels includes a light-emitting device and a pixel driving circuit for driving the light-emitting device; the pixel driving circuit includes at least two oxide transistors and a storage capacitor; the storage capacitor includes a first electrode and a second electrode sequentially facing away from the base substrate and arranged opposite to each other; in the at least two oxide transistors, a distance between a gate of one oxide transistor and an active layer of the one oxide transistor is different from a distance between a gate of at least one of other oxide transistors and an active layer of the at least one of other oxide transistors.

### CROSS REFERENCE TO RELATED APPLICATIONS

This application is a US National Stage of International Application No. PCT/CN2023/089941, filed on Apr. 21, 2023, which claims priority to Chinese patent application No. 202210661034.X, filed with the China National Intellectual Property Administration on Jun. 13, 2022, and entitled “Display Substrate, Manufacturing Method Therefor, and Display Device,” the content of which is hereby incorporated by reference in its entirety.

### TECHNICAL FIELD

The present disclosure relates to the technical field of display, and in particular to a display substrate, a manufacturing method therefor, and a display device.

### BACKGROUND

Organic Electro-luminescent Display (OLED) panels have gradually become the mainstream in the display field due to their excellent performance such as low power consumption, high color saturation, wide viewing angle, thin thickness, and flexibility. The OLED panels can be widely used in terminal products such as smart phones, tablets, and televisions.

Currently, the driving circuit of OLED generally uses low temperature polysilicon (LTPS) as the channel of the driver thin film transistor (DTFT). LTPS has higher mobility than a-Si, but due to the grain boundaries generated during crystallization and the uneven distribution of grain size, LTPS often requires complex driving circuits to compensate for the threshold voltage (Vth) of the DTFT. The ultimate result of the compensation is to eliminate the display Mura caused by the non-uniformity of Vth in different DTFTs. The 7T1C pixel compensation circuit as shown in FIG. 1 is often used. The pixel compensation circuit includes seven transistors including T1, T2, T3, T4, T5, T6 and T7, where T3 is a DTFT, and Cst is a storage capacitor.

Currently, in order to meet the demand for reducing leakage at low frequencies, an LTPO backplane that combines LTPS TFT and oxide TFT is often used. The driving circuit in the LTPO backplane can replace T1 and T2 with oxide TFTs based on FIG. 1. The low leakage characteristic of the Oxide TFT is utilized to reduce the flicker caused by Cst leakage at low frequencies. How to avoid the non-uniformity of Vth in different DTFTs has become a technical problem that needs to be solved urgently.

### SUMMARY

The present disclosure provides a display substrate, a manufacturing method therefor and a display device, to ensure the uniformity of the threshold voltages of the thin film transistors and improve the display effect.

In a first aspect, embodiments of the present disclosure provide a display substrate including:
a base substrate; and
a plurality of sub-pixels arranged in an array on the base substrate; where each of the sub-pixels includes a light-emitting device and a pixel driving circuit for driving the light-emitting device, the pixel driving circuit includes at least two oxide transistors and a storage capacitor;
where the storage capacitor includes a first electrode and a second electrode which are sequentially facing away from the base substrate and arranged opposite to each other; in the at least two oxide transistors, a distance between a gate of one oxide transistor and an active layer in the one oxide transistor is different from a distance between a gate of at least one of other oxide transistors and an active layer of the at least one of other oxide transistors; and the one oxide transistor in the at least two oxide transistors with a greater distance between the gate and the active layer is arranged above the second electrode.

In a possible implementation, the second electrode partially overlaps with active layers of the at least two oxide transistors.

In a possible implementation, the pixel driving circuit further includes at least one polysilicon transistor coupled with the at least two oxide transistors; a gate of the at least one polysilicon transistor is arranged in a same layer as the first electrode, and the at least two oxide transistors are arranged on a side of the second electrode facing away from the base substrate.

In a possible implementation, orthographic projections of the active layers of the at least two oxide transistors on the base substrate completely fall within an orthographic projection of an active layer of the at least one polysilicon transistor on the base substrate.

In a possible implementation, an orthographic projection of the second electrode on the base substrate completely falls within an orthographic projection of the first electrode on the base substrate.

In a possible implementation, the at least two oxide transistors include a compensation transistor and a first reset transistor, and the pixel driving circuit further includes a driving transistor, a first light emitting control transistor, a second light emitting control transistor, a data writing transistor, and a second reset transistor, which are polysilicon transistors; where:
the compensation transistor is respectively coupled between a gate of the driving transistor and a first electrode of the driving transistor, and a gate of the compensation transistor is coupled with a first scanning control terminal;
the first reset transistor is respectively coupled between the gate of the driving transistor and an initialization signal terminal, and a gate of the first reset transistor is coupled with the first scanning control terminal;
the storage capacitor is respectively coupled between a first power supply terminal and the gate of the driving transistor;
the first light emitting control transistor is respectively coupled between the first power supply terminal and a second electrode of the driving transistor, and a gate of the first light emitting control transistor is coupled with a light emitting control terminal;
the second light emitting control transistor is respectively coupled between a first electrode of the driving transistor and a first electrode of the light-emitting device, and a gate of the second light emitting control transistor is coupled with the light emitting control terminal;
the data writing transistor is respectively coupled between the second electrode of the driving transistor and a data signal terminal, and a gate of the data writing transistor is coupled with a second scanning control terminal;
the second reset transistor is respectively coupled between the first electrode of the light-emitting device and the initialization signal terminal, and a gate of the second reset transistor is coupled with the second scanning control terminal; and
a second electrode of the light-emitting device is coupled with a second power supply terminal.

In a possible implementation, the compensation transistor and the first reset transistor are both N-type transistors; and the driving transistor, the first light emitting control transistor, the second light emitting control transistor, the data writing transistor and the second reset transistor are all P-type transistors.

In a second aspect, embodiments of the present disclosure further provide a display device, including: the display substrate as described in any one of the above embodiments.

In a third aspect, embodiments of the present disclosure further provide a method for manufacturing the display substrate as described in any one of the above embodiments, including:
forming patterns of the first electrode and the second electrode of the storage capacitor and patterns of active layers of the at least two oxide transistors on the base substrate, sequentially; and
forming a pattern of a gate insulating layer on a side of the active layers of the at least two oxide transistors facing away from the base substrate, so that in the at least two oxide transistors, a distance between a gate and an active layer of one transistor arranged above the second electrode is greater than a distance between a gate and an active layer of other transistors.

In a possible implementation, forming the pattern of the gate insulating layer on the side of the active layers of the at least two oxide transistors facing away from the base substrate, includes:
depositing the gate insulating layer with a first thickness on the side of the active layers of the at least two oxide transistors facing away from the base substrate;
coating a photoresist on the gate insulating layer;
patterning the photoresist by using a composition process, and removing the photoresist at positions corresponding to the other transistors, to form a pattern of the photoresist;
etching the gate insulating layer at the positions corresponding to the other transistor by a third thickness according to the pattern of the photoresist, where a difference between the first thickness and the third thickness is a second thickness, and the first thickness is greater than the second thickness; and
removing the pattern of the photoresist to form the pattern of the gate insulating layer.

Beneficial effects of the present disclosure are as follows.

Embodiments of the present disclosure provide a display substrate, a manufacturing method therefor and a display device, the display substrate includes: a base substrate; and a plurality of sub-pixels arranged in an array on the base substrate; where each of the sub-pixels includes a light-emitting device and a pixel driving circuit for driving the light-emitting device, the pixel driving circuit includes at least two oxide transistors and a storage capacitor; the storage capacitor includes a first electrode and a second electrode which are sequentially facing away from the base substrate and arranged opposite to each other; in the at least two oxide transistors, a distance between a gate of one oxide transistor and an active layer of the one oxide transistor is different from a distance between a gate of at least one of other oxide transistors and an active layer of the at least one of other oxide transistors; and the one oxide transistor in the at least two oxide transistors with a greater distance between the gate and the active layer is arranged above the second electrode. That is, in the at least two oxide transistors, the distance between the gate and the active layer of the transistor located above the second electrode is greater than the distance between the gate and the active layer of the other transistors not located above the second electrode. In this way, while reducing the layout space of the oxide transistor and improving the resolution, even if the second electrode receives a constant voltage signal causing the threshold voltage of the transistor above it to shift, the greater distance between the gate and the active layer of the transistor can correspondingly cause its threshold voltage to shift in the opposite direction, and the two offset each other, ensuring the uniformity of the threshold voltages of the transistors and improving the display effect.

### BRIEF DESCRIPTION OF FIGURES

FIG. 1 is a schematic structural diagram of a 7T1C pixel compensation circuit in the related art.

FIG. 2 is a schematic structural diagram of a driving circuit used in an LTPO backplane in the related art.

FIG. 3 is a schematic structural diagram of a film layer corresponding to FIG. 2.

FIG. 4 is another schematic structural diagram of a film layer corresponding to FIG. 2.

FIG. 5 is a schematic structural diagram of a top view of a display substrate according to embodiments of the present disclosure.

FIG. 6 is a schematic structural diagram of a cross-sectional view along a direction indicated by MM in FIG. 5.

FIG. 7 is a schematic structural diagram of a pixel driving circuit in a display substrate according to embodiments of the present disclosure.

FIG. 8 is a flow chart of a method for manufacturing a display substrate according to embodiments of the present disclosure.

FIG. 9 is a flow chart of the step S102 in FIG. 8.

FIG. 10 is a process flow chart corresponding to FIG. 8 and FIG. 9.

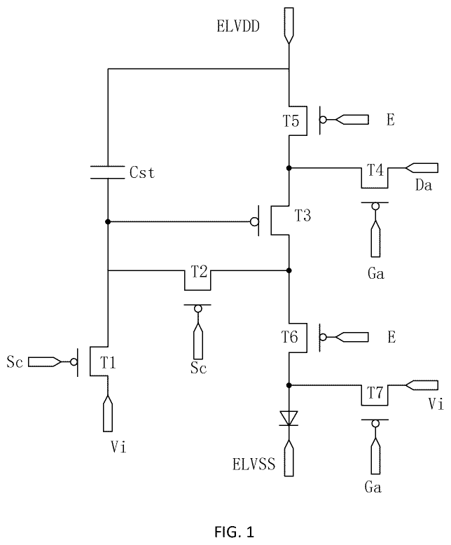

### DETAILED DESCRIPTION

In order to make the purpose, technical solutions and advantages of embodiments of the present disclosure more clear, the technical solutions of the embodiments of the present disclosure will be clearly and completely described below in conjunction with the drawings of embodiments of the present disclosure. Obviously, the described embodiments are some, but not all, of the embodiments of the present disclosure. And the embodiments and features in the embodiments of the present disclosure may be combined with each other without conflict. Based on the described embodiments of the present disclosure, all other embodiments obtained by those of ordinary skill in the art without creative efforts fall within the scope of the present disclosure.

Unless otherwise defined, technical terms or scientific terms used in this disclosure shall have the usual meaning understood by a person with ordinary skill in the art to which this disclosure belongs. Words such as “including” or “comprising” used in the disclosure refer to the components or objects that appear before the word, including those listed components or objects after the word and their equivalents, without excluding other components or objects.

It should be noted that the sizes and shapes of the figures in the drawings do not reflect true proportions and are only intended to illustrate the present disclosure. And, the same or similar reference numbers throughout represent the same or similar components or elements having the same or similar functions.

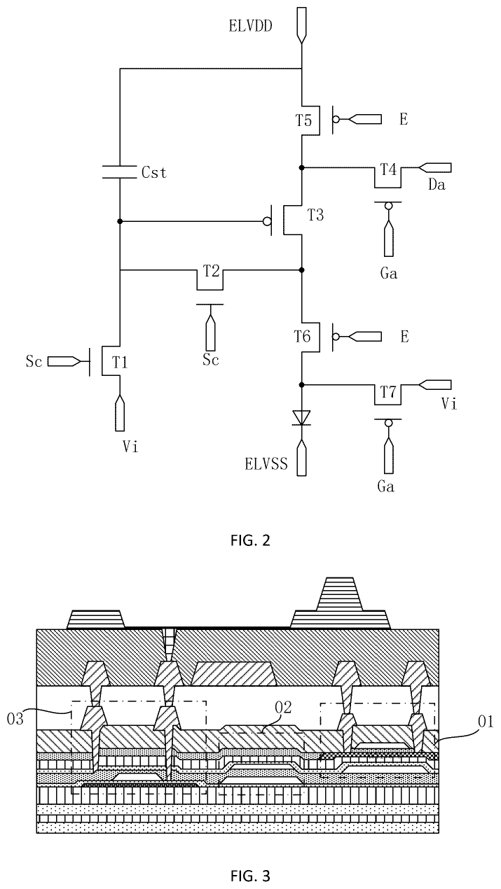

In the related art, the LTPO backplane can adopt the driving circuit shown in FIG. 2 and the film layer structure shown in FIG. 3. Where, 01 represents an oxide TFT, 02 represents a storage capacitor, and 03 represents an LTPS TFT. The pitch of the sub-pixels finally formed is 56 μm, and the corresponding pixel density (Pixels Per Inch, PPI) is about 450. However, in the backplane process corresponding to FIG. 3, the oxide TFT is designed to avoid all film layers of the LTPS TFT below, resulting in lower resolution.

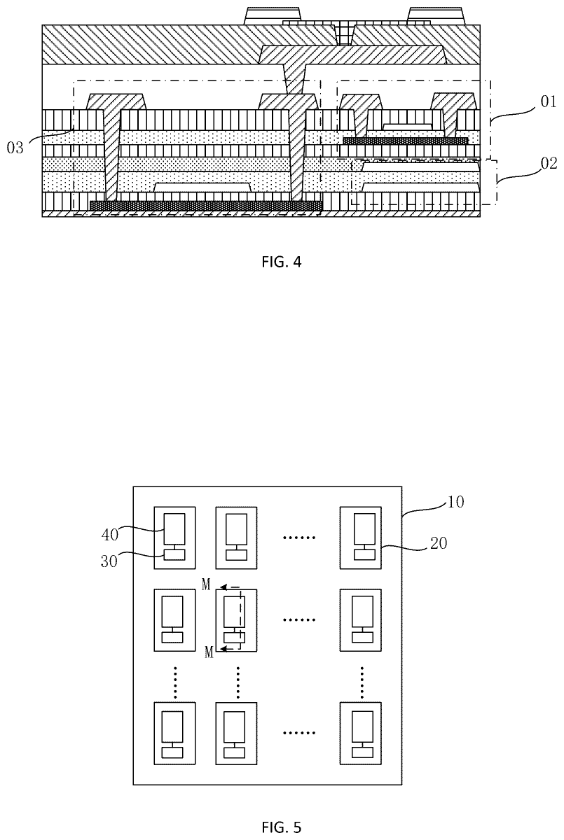

In order to improve the PPI of the LTPO backplane, the film layer structure shown in FIG. 4 can be used, and one of the oxide TFTs can be placed above Cst. Since the upper electrode of Cst is connected with ELVDD, and ELVDD is a DC voltage of 4.6V, it is equivalent to connecting a DC bottom gate under the channel of the oxide TFT. Since the DC voltage is constant, it will not cause a jump in the channel state when the circuit is working, the pitch of the sub-pixels finally formed is 42 μm, and the corresponding PPI is about 600 which is higher than that of FIG. 3. The inventors found in actual research that in the actual circuit layout, the size of Cst is generally limited according to design requirements, and both T1 and T2 cannot be placed above Cst, that is, only one of T1 and T2 can be placed above Cst. In this case, the DC bottom gate loading 4.6V will have a certain degree of impact on the Vth of the transistor placed above it. For the film structure shown in FIG. 4, in actual testing, when ELVDD is loaded with a positive voltage of 4.6V, the oxide TFT located on the DC bottom gate will be negatively biased by about 1.2V. For T1 and T2, if only one of the transistors T1 and T2 is placed above the Cst, the turn-on voltages of the two oxide TFTs will deviate, thus causing Ion deviation. In practical applications, this situation may cause timing problems due to abnormal charging and discharging of the capacitor. In addition, since channels of T1 transistor and T2 transistor are made in the same layer, Vth cannot be adjusted by channel doping, nor can the channel mobility of the same-layer TFTs be adjusted by adjusting the oxygen content of indium gallium zinc oxide (IGZO).

In view of this, embodiments of the present disclosure provide a display substrate, a manufacturing method therefor, and a display device, to ensure the uniformity of the threshold voltages of the thin film transistors and improve the display effect.

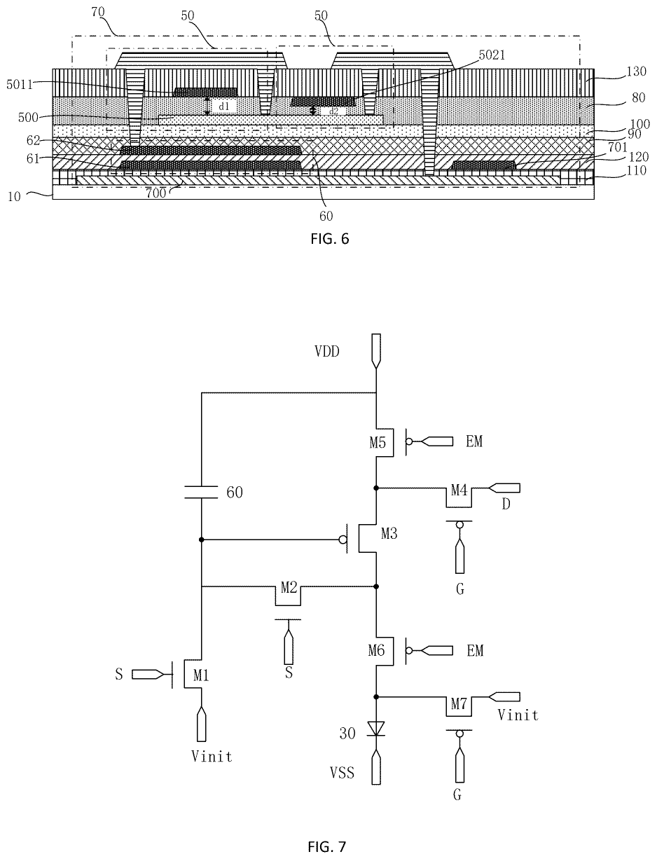

As shown in FIG. 5 and FIG. 6, embodiments of the present disclosure provide a display substrate. FIG. 5 is a schematic structural diagram of a top view of a display substrate, and FIG. 6 is a schematic structural diagram of a cross-sectional view along a direction indicated by MM in FIG. 5, and the display substrate includes: a base substrate 10 and a plurality of sub-pixels 20 arranged in an array on the base substrate 10, each of the sub-pixels 20 includes a light-emitting device 30 and a pixel driving circuit 40 for driving the light-emitting device 30, where the pixel driving circuit 40 includes at least two oxide transistors 50 and a storage capacitor 60.

The storage capacitor 60 includes a first electrode 61 and a second electrode 62 sequentially facing away from the base substrate 10 and arranged opposite to each other; in the at least two oxide transistors 50, a distance between a gate of one oxide transistor and an active layer of the one oxide transistor is different from a distance between a gate of at least one of other oxide transistors and an active layer of the at least one of other oxide transistors; and the oxide transistor in the at least two oxide transistors 50 with a greater distance between the gate and the active layer is arranged above the second electrode 62. In a specific implementation process, the display substrate includes a base substrate 10 and a plurality of sub-pixels 20 arranged in an array on the base substrate 10. The base substrate 10 may be a rigid substrate or a flexible substrate, which is not limited herein. In addition, the specific number of the plurality of sub-pixels 20 may be set according to actual application requirements and is not limited here. Each of the sub-pixels 20 includes a light-emitting device 30 and a pixel driving circuit 40 for driving the light-emitting device 30. The pixel driving circuit 40 includes at least two oxide transistors 50 and a storage capacitor 60. At least two oxide transistors 50 included in each pixel driving circuit 40 may be two or three, and may be set according to actual application requirements, which is not limited here.

Still referring to FIG. 6, the storage capacitor 60 includes a first electrode 61 and a second electrode 62 sequentially facing away from the base substrate 10 and are arranged opposite to each other. In the at least two oxide transistors 50, a distance between a gate of one oxide transistor and an active layer of the one oxide transistor is different from a distance between a gate of at least one of other oxide transistors and an active layer of the at least one of other oxide transistors; and the one oxide transistor in the at least two oxide transistors 50 with a greater distance between the gate and the active layer is arranged above the second electrode 62. That is, in the at least two oxide transistors 50, the distance between the gate and the active layer of the transistor located above the second electrode 62 is greater than the distance between the gate and the active layer of the other transistors not located above the second electrode 62. In addition, the second electrode 62 may be configured to receive a constant voltage signal, so that the second electrode 62 may serve as a bottom gate of a transistor located above the second electrode, correspondingly improving the stability of the transistor. Since in the at least two oxide transistors 50, the distance between the gate and the active layer of the transistor located above the second electrode 62 is greater than the distance between the gate and the active layer of the other transistors not located above the second electrode 62, the layout space of the oxide transistors can be reduced and the resolution can be improved. Even if the second electrode 62 receives a constant voltage signal causing the threshold voltage of the transistor above it to shift, the greater distance between the gate and the active layer of the transistor can correspondingly cause its threshold voltage to shift in an opposite direction, and the two offset each other, ensuring the uniformity of the threshold voltages of the transistors and improving the display effect.

In a specific implementation process, the number of transistors with the greater distance between the gate and the active layer in the at least two oxide transistors 50 may be one or more. Correspondingly, the number of transistors located above the second electrode 62 in the at least two oxide transistors 50 may be one or more. Of course, the number of oxide transistors located above the second electrode 62 may be set according to actual application requirements and is not limited here. Furthermore, the number of transistors not located above the second electrode 62 in the at least two oxide transistors 50 may be one or more, which is not limited herein. FIG. 6 schematically shows that one of the two oxide transistors is located above the second electrode 62, and the other transistor is not located above the second electrode 62.

Still taking FIG. 6 as an example, the distance between the gate and the active layer of the transistor located above the second electrode 62 is d1, and the distance between the gate and the active layer of the other transistor is d2, where d1>d2. In this way, when the threshold voltage of the transistor located above the second electrode 62 shifts due to the second electrode 62 receiving a constant voltage signal, the greater distance between the gate and the active layer of the transistor can correspondingly cause its threshold voltage to shift in the opposite direction, and the two offset each other, ensuring the uniformity of the threshold voltages of the transistors and improving the display effect. It should be noted that the specific value of the distance between the gate 5011 and the active layer of the oxide transistor located above the second electrode 62, as well as the specific value of the distance between the gate 5021 and the active layer of other transistors can be set according to actual application requirements and are not limited here.

It should be noted that the inventors have found that, according to the classic Vth formula of MOSFET:

$${V}_{TN} = {V}_{G} {\vert}_{{ϕ}_{s} = 2 {ϕ}_{fp}} = {V}_{ox} {\vert}_{{ϕ}_{s} = 2 {ϕ}_{fp}} + 2 {ϕ}_{fp} + {ϕ}_{ms} = \frac{\vert {Q}_{SDmax}^{′} \vert}{{C}_{ox}} - \frac{{Q}_{ss}^{′}}{{C}_{ox}} + 2 {ϕ}_{fp} + {ϕ}_{ms} ,$$

for the N-type oxide transistor disposed above the second electrode 62 of the storage capacitor 60, the N-type oxide transistor is affected by the gate dielectric layer capacitance Cox, and the larger the Cox, the smaller the Vth of the N-type oxide transistor. When the thickness of the gate dielectric layer is reduced, Vth is negatively biased. When the thickness of the gate dielectric layer is increased, Vth is positively biased. In actual tests, the width-to-length ratio of the N-type oxide transistor is: W/L=2.5/4. When the voltage loaded on the data signal terminal is 10.1 V, the Vth of the corresponding device when the gate dielectric layer thickness is 1000 angstroms is about 0.5 V more negative than the Vth of the corresponding device when the gate dielectric layer thickness is 1400 angstroms. As a result, in embodiments of the present disclosure, in the at least two oxide transistors 50, by setting the distance between the gate 5011 and the active layer of the transistor located above the second electrode 62 to be greater than the distance between the gate 5021 and the active layer of other transistors, the influence of the threshold voltage shift of the transistor located above the second electrode 62 due to the second electrode 62 receiving a constant voltage signal can be offset, effectively ensuring the uniformity of Vth.

Still referring to FIG. 6, the second electrode 62 partially overlaps the active layers 500 of the at least two oxide transistors 50. In this way, the channels of the at least two oxide transistors 50 can be protected to a certain extent by the second electrode 62, ensuring the driving capability of the pixel driving circuit 40.

In embodiments of the present disclosure, still referring to FIG. 6, the pixel driving circuit 40 further includes at least one polysilicon transistor 70 coupled with the at least two oxide transistors 50. A gate 701 of the at least one polysilicon transistor 70 is arranged in a same layer as the first electrode 61, and the at least two oxide transistors 50 are arranged on a side of the second electrode 62 facing away from the substrate 10.

In a specific implementation process, the at least one polysilicon transistor 70 coupled with the at least two oxide transistors 50 may be one or more, which is not limited here. The gate 701 of the at least one polysilicon transistor 70 is arranged on the same layer as the first electrode 61. In an actual process, the gate 701 of the at least one polysilicon transistor 70 and the first electrode 61 may be manufactured in the same layer, simplifying the manufacturing process. Furthermore, the at least two oxide transistors 50 are arranged on a side of the second electrode 62 facing away from the base substrate 10, so that layout space can be saved, improving resolution.

In embodiments of the present disclosure, still referring to FIG. 6, orthographic projections of the active layers 500 of the at least two oxide transistors 50 on the base substrate 10 completely fall within an orthographic projection of an active layer 700 of the at least one polysilicon transistor 70 on the base substrate 10.

In a specific implementation process, the orthographic projections of the active layers 500 of the at least two oxide transistors 50 on the base substrate 10 completely fall within the orthographic projection of the active layer 700 of the at least one polysilicon transistor 70 on the base substrate 10, saving layout space and improving resolution.

In embodiments of the present disclosure, still referring to FIG. 6, an orthographic projection of the second electrode 62 on the base substrate 10 completely falls within an orthographic projection of the first electrode 61 on the base substrate 10. In this way, the first electrode 61 can protect the second electrode 62 to a certain extent, ensuring the performance of the storage capacitor 60.

It should be noted that, still referring to FIG. 6, the display substrate according to embodiments of the present disclosure also includes a gate insulating layer 80 arranged between the gate and the active layer of the oxide transistor 50, a first interlayer insulating layer 90 and a buffer layer 100 arranged between the second electrode 62 and the active layer 500 of the oxide transistor 50, a first gate insulating layer 110 arranged between the active layer 700 of the polysilicon transistor 70 and the first electrode 61, a second gate insulating layer 120 arranged between the first electrode 61 and the second electrode 62, and a second interlayer insulating layer 130 arranged on the side of the gate of the oxide transistor 50 facing away from the base substrate 10. Of course, other film layers of the display substrate may be provided according to actual application requirements. For details, specific implementation can refer to relevant technologies, which will not be described in detail here.

In embodiments of the present disclosure, the pixel driving circuit 40 may be configured in a variety of ways. In one exemplary embodiment, FIG. 7 is a schematic structural diagram of a pixel driving circuit 40. The at least two oxide transistors 50 include a compensation transistor M2 and a first reset transistor M1. The pixel driving circuit 40 further includes a driving transistor M3, a first light emitting control transistor M5, a second light emitting control transistor M6, a data writing transistor M4, and a second reset transistor M7, which are polysilicon transistors.

The compensation transistor M2 is respectively coupled between a gate and a first electrode of the driving transistor M3, and a gate of the compensation transistor is coupled with a first scanning control terminal S.

The first reset transistor M1 is respectively coupled between the gate of the driving transistor M3 and an initialization signal terminal Vinit, and a gate of the first reset transistor is coupled with the first scanning control terminal S.

The storage capacitor 60 is respectively coupled between a first power supply terminal VDD and the gate of the driving transistor M3.

The first light emitting control transistor M5 is respectively coupled between the first power supply terminal VDD and a second electrode of the driving transistor M3, and a gate of the first light emitting control transistor is coupled with a light emitting control terminal EM.

The second light emitting control transistor M6 is respectively coupled between a first electrode of the driving transistor M3 and a first electrode of the light-emitting device 30, and a gate of the second light emitting control transistor is coupled with the light emitting control terminal EM.

The data writing transistor M4 is respectively coupled between the second electrode of the driving transistor M3 and a data signal terminal D, and a gate of the data writing transistor is coupled with a second scanning control terminal G.

The second reset transistor M7 is respectively coupled between the first electrode of the light-emitting device 30 and the initialization signal terminal Vinit, and a gate the second reset transistor is coupled with the second scanning control terminal G.

A second electrode of the light-emitting device 30 is coupled with a second power supply terminal VSS.

Still referring to FIG. 7, in embodiments of the present disclosure, the pixel driving circuit 40 includes seven transistors including a compensation transistor M2, a first reset transistor M1, a driving transistor M3, a first light emitting control transistor M5, a second light emitting control transistor M6, a data writing transistor M4 and a second reset transistor M7. The compensation transistor M2 and the first reset transistor M1 are both oxide transistors 50, and the driving transistor M3, the first light emitting control transistor M5, the second light emitting control transistor M6, the data writing transistor M4 and the second reset transistor M7 are all polysilicon transistors 70. The compensation transistor M2 is respectively coupled between the gate and the first electrode of the driving transistor M3, and the gate of the compensation transistor is coupled with the first scanning control terminal S. The first reset transistor M1 is coupled between the gate of the driving transistor M3 and the initialization signal terminal Vinit, and the gate of the first reset transistor is coupled with the first scanning control terminal S. In this way, when the first reset transistor M1 is turned on, the gate of the driving transistor M3 can be reset through the first scanning control terminal S.

The storage capacitor 60 is respectively coupled between the first power supply terminal VDD and the gate of the driving transistor M3. The first power supply terminal VDD may be a high potential power supply terminal and may provide a constant high potential signal. The data writing transistor M4 is respectively coupled between the second electrode of the driving transistor M3 and the data signal terminal D, and the gate of the data writing transistor is coupled with the second scanning control terminal G. In this way, when the data writing transistor M4 is turned on, the second electrode of the driving transistor M3 can be charged through the data signal terminal D, and when the compensation transistor M2 is turned on, the threshold voltage of the driving transistor M3 and the data signal provided by the data signal terminal D can be written into the gate of the driving transistor M3, achieving compensation for the threshold voltage of the driving transistor M3. In addition, the first light emitting control transistor M5 is respectively coupled between the first power supply terminal VDD and the second electrode of the driving transistor M3, and the gate of the first light emitting control transistor is coupled with the light emitting control terminal; the second light emitting control transistor M6 is respectively coupled between the second electrode of the driving transistor M3 and the data signal terminal D, and the gate of the second light emitting control transistor is coupled with the light emitting control terminal. In this way, when the first light emitting control transistor M5 and the second light emitting control transistor M6 are both turned on, the light-emitting device 30 emits light.

Moreover, the second reset transistor M7 is respectively coupled between the first electrode of the light-emitting device 30 and the initialization signal terminal Vinit, and the gate of the second reset transistor is coupled with the second scanning control terminal G. In this way, when the second reset transistor M7 is turned on, the initialization signal provided by the initialization signal terminal Vinit can be written into the first electrode of the light-emitting device 30. When the first electrode of the light-emitting device 30 is an anode, the anode is reset, ensuring low-frequency display. The second electrode of the light-emitting device 30 is coupled with the second power supply terminal VSS. The second power supply terminal VSS may be a low potential power supply terminal and may provide a constant low potential signal. The storage capacitor 60 is respectively coupled between the first power supply terminal VDD and the gate of the driving transistor M3. The storage capacitor 60 ensures that the potential of the gate of the driving transistor M3 is stable, ensuring the driving effect of the pixel driving circuit 40.

Still referring to FIG. 7, the compensation transistor M2 and the first reset transistor M1 are both N-type transistors, and the driving transistor M3, the first light emitting control transistor M5, the second light emitting control transistor M6, the data writing transistor M4 and the second reset transistor M7 are all P-type transistors. In a specific implementation process, the active layer of the compensation transistor M2 and the active layer of the first reset transistor M1 are made of metal oxide semiconductor materials, which may be metal oxides, such as IGZO or indium tin zinc oxide (ITZO), which are not limited here. Accordingly, the compensation transistor M2 and the first reset transistor M1 may be N-type transistors using metal oxide semiconductor materials as active layers. In this way, during the actual operation of the pixel driving circuit 40, the compensation transistor M2 and the first reset transistor M1 have a relatively small leakage current. The active layers of the driving transistor M3, the first light emitting control transistor M5, the second light emitting control transistor M6, the data writing transistor M4, and the second reset transistor M7 are low temperature polysilicon materials. Accordingly, the driving transistor M3, the first light emitting control transistor M5, the second light emitting control transistor M6, the data writing transistor M4, and the second reset transistor M7 may be P-type transistors using the low temperature polysilicon materials as an active layer. In this way, in the actual operation of the pixel driving circuit 40, the driving transistor M3, the first light emitting control transistor M5, the second light emitting control transistor M6, the data writing transistor M4 and the second reset transistor M7 have higher mobility, lower power consumption, and can be made thinner. As a result, the pixel driving circuit 40 shown in FIG. 7 is actually an LTPO pixel circuit, ensuring that the leakage current of the gate of the driving transistor M3 is small and the power consumption is low.

Still referring to the circuit structure shown in FIG. 7, in one exemplary embodiment, the first reset transistor M1 can be arranged above the second electrode 62, and the compensation transistor M2 can be used as another transistor and not arranged above the second electrode 62; the distance between the gate of the first reset transistor M1 and the active layer of the first reset transistor M1 is greater than the distance between the gate of the compensation transistor M2 and the active layer of the compensation transistor M2. In another exemplary embodiment, the compensation transistor M2 can be arranged above the second electrode 62, and the first reset transistor M1 can be used as another transistor and not arranged above the second electrode 62; the distance between the gate of the compensation transistor M2 and the active layer of the compensation transistor M2 is greater than the distance between the gate of the first reset transistor M1 and the active layer of the first reset transistor M1. In a specific implementation process, the transistor arranged above the second electrode 62 in the at least two oxide transistors 50 may be provided according to actual application requirements, which is not limited here.

It should be noted that the light-emitting device 30 in embodiments of the present disclosure can be set as an electroluminescent diode, such as at least one of: an organic light emitting diode (OLED), a quantum dot light emitting diode (QLED), and a micro inorganic light emitting diode (micro Light Emitting Diode/Mini Light Emitting Diode), which is not limited here. The light-emitting device 30 may include an anode, a light emitting layer, and a cathode which are stacked. Furthermore, the light emitting layer may also include film layers such as a hole injection layer, a hole transport layer, an electron transport layer, and an electron injection layer. Of course, in practical applications, the light-emitting device 30 can be designed according to the requirements of the actual application environment, which is not limited here.

Functions of the first electrode and the second electrode of each transistor mentioned above can be interchangeable according to the corresponding transistor type and the signal at the signal terminal. For example, the first electrode may be the source electrode and the corresponding second electrode may be the drain electrode. For another example, the first electrode may be the drain electrode and the corresponding second electrode may be the source electrode. This is not limited here. Each transistor may be a thin film transistor (TFT) or a metal oxide semiconductor (MOS) field effect transistor, which is not limited here. Of course, the specific type of each transistor can also be set according to actual application needs, which is not limited here.

The above is only an example to illustrate the specific structure of the display substrate according to embodiments of the present disclosure. In specific implementation, the specific structure of the above display substrate is not limited to the above structure according to embodiments of the present disclosure, and can also be other structures known to those skilled in the art. These are all within the protection scope of the present disclosure and are not limited here.

Based on the same inventive concept, embodiments of the present disclosure further provide a display device, which includes any one of the above-mentioned display substrates. The principle of solving the problem by the display device is similar to that of the aforementioned display substrate, so the implementation of the display device can refer to the implementation of the aforementioned display substrate, and the repeated parts will not be repeated.

In a specific implementation process, the display device according to embodiments of the present disclosure can be any product or component with a display function, such as a mobile phone, a tablet computer, a television, a monitor, a laptop computer, a digital photo frame, a navigator, etc. Other essential components of the display device should be understood by those skilled in the art and will not be described in detail herein and should not be construed as limiting the present disclosure.

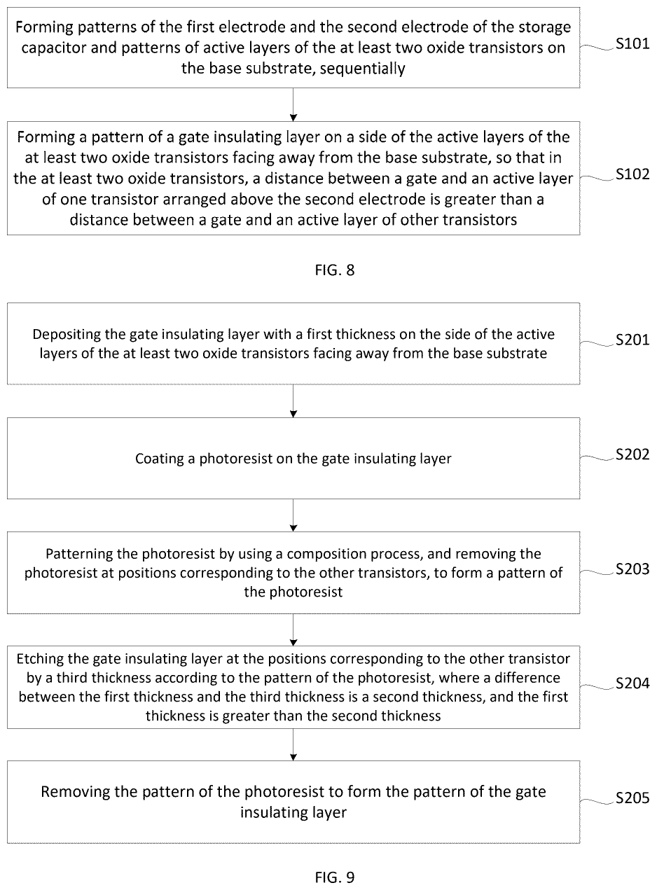

Based on the same inventive concept, as shown in FIG. 8, embodiments of the present disclosure further provides a method for manufacturing the above-mentioned display substrate, the manufacturing method includes following steps.

S101: forming patterns of the first electrode and the second electrode of the storage capacitor and patterns of active layers of the at least two oxide transistors on the base substrate, sequentially.

S102: forming a pattern of a gate insulating layer on a side of the active layers of the at least two oxide transistors facing away from the base substrate, so that in the at least two oxide transistors, a distance between a gate and an active layer of one transistor arranged above the second electrode is greater than a distance between a gate and an active layer the other transistors.

In embodiments of the present disclosure, as shown in FIG. 9, step S102: forming a pattern of a gate insulating layer on a side of the active layers of the at least two oxide transistors facing away from the base substrate, includes following steps.

S201: depositing the gate insulating layer with a first thickness on the side of the active layers of the at least two oxide transistors facing away from the base substrate.

S202: coating a photoresist on the gate insulating layer.

S203: patterning the photoresist by using a composition process, and removing the photoresist at positions corresponding to the other transistors, to form a pattern of the photoresist.

S204: etching the gate insulating layer at the positions corresponding to the other transistor by a third thickness according to the pattern of the photoresist, where a difference between the first thickness and the third thickness is a second thickness, and the first thickness is greater than the second thickness.

S205: removing the pattern of the photoresist to form the pattern of the gate insulating layer.

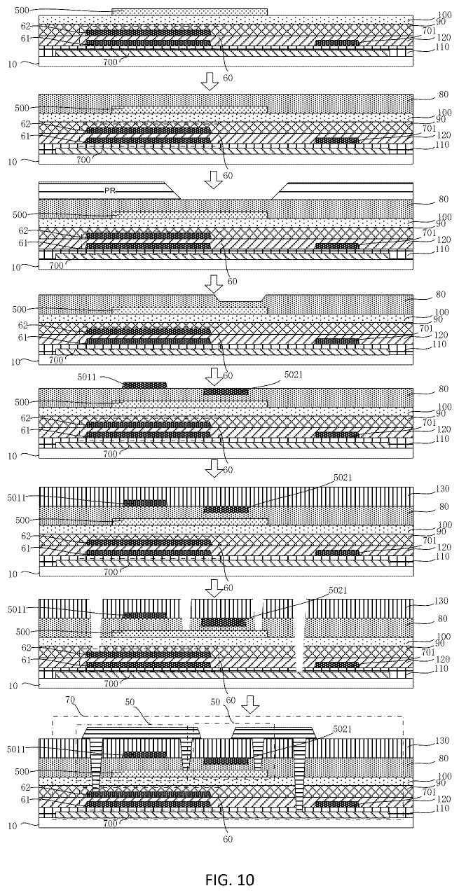

The method flow charts of FIGS. 8 and 9 are explained below by taking the manufacture of the display substrate shown in FIG. 6 as an example and combining with the process shown in FIG. 10.

Firstly, a pattern of an active layer 700 of a polysilicon transistor 70, a first gate insulating layer 110, a pattern of a first electrode 61, a second gate insulating layer 120, a pattern of a second electrode 62, a first interlayer insulating layer 90, a buffer layer 100 and a pattern of an active layer 500 of an oxide transistor 50 are sequentially formed on a base substrate 1; and then, a gate insulating layer 80 of a first thickness is deposited on a side of the active layer 500 of the oxide transistor 50 facing away from the base substrate 10. In one exemplary embodiment, since the DC voltage loaded on the second electrode 62 is +4.6 V, for the N-type oxide transistor, the Vth is negatively biased. When the other film layer structure parameters except the gate insulation layer 80 in FIG. 6 are the same as the corresponding film layer structure in FIG. 3, the first thickness is greater than the thickness of the gate insulation layer 80 in FIG. 3, so that the Vth of the N-type oxide transistor is positively biased. In this way, when the pixel driving circuit 40 is working, the influence of the DC voltage can be offset, restoring the N-type oxide transistor to a normal level. In one exemplary embodiment, the first thickness may be 2000 angstroms. Of course, the specific value of the first thickness can also be set according to actual application requirements, which is not limited here.

Then, a photoresist PR is coated on the gate insulating layer 80 having the first thickness. The photoresist PR is patterned by using a composition process, and the photoresist PR at positions corresponding to other transistors 502 is removed to form a pattern of the photoresist PR. In one exemplary embodiment, the photoresist PR at the channel of TFT that is not arranged above the storage capacitor 60 can be removed by exposure-development, and then this portion can be etched by a dry etching process. The gate insulating layer 80 at the corresponding position of other transistors 502 may be etched away by a third thickness according to the pattern of the photoresist PR. In one exemplary embodiment, the third thickness is 1000 angstroms. In this case, the final thickness of the gate insulating layer 80 at this position is 1000 angstroms. In this way, the uniformity of the threshold voltages of transistors is ensured.

Then, a gate of the oxide transistor 50 is deposited and a pattern of the gate of the oxide transistor 50 is formed. The second interlayer insulating layer 130 is deposited on a side of the gate of the oxide transistor 50 facing away from the base substrate 10. Then, via holes are laid out and etched. Considering that the active layer 700 of the polysilicon transistor 70 needs to be cleaned in a mass production process, this can be done through two masks. The specific layout and etching process can refer to the specific implementation in the related art and will not be described in detail here. Then, a source-drain electrode layer is deposited, and the source-drain electrodes of the oxide transistor 50 and the source-drain electrodes of the polysilicon transistor 70 are formed in the same layer. It should be noted that the figures only illustrate the position of the metal interconnection, and does not illustrate the signal lines corresponding to the data signal terminal D and the first power supply terminal VDD. In practical applications, the corresponding signal lines can be laid out using a single-layer source-drain electrode layer or a double-layer source-drain electrode layer according to layout requirements, which will not be described in detail here. In addition, the manufacturing process of other film layers in the display substrate can refer to the specific implementation in the related art and will not be described in detail here.

Embodiments of the present disclosure provide a display substrate, a manufacturing method therefor and a display device, the display substrate includes: a base substrate 10; and a plurality of sub-pixels 20 arranged in an array on the base substrate 10; where each of the sub-pixels 20 includes a light-emitting device 30 and a pixel driving circuit 40 for driving the light-emitting device 30, the pixel driving circuit 40 includes at least two oxide transistors 50 and a storage capacitor 60; the storage capacitor 60 includes a first electrode 61 and a second electrode 62 sequentially facing away from the base substrate 10 and arranged opposite to each other; in the at least two oxide transistors 50, a distance between a gate of one oxide transistor and an active layer of the one oxide transistor is different from a distance between a gate of at least one of other oxide transistors and an active layer of the at least one of other oxide transistors; and the one oxide transistor in the at least two oxide transistors with a greater distance between the gate and the active layer is arranged above the second electrode 62. That is, in the at least two oxide transistors 50, the distance between the gate and the active layer of the transistor located above the second electrode 62 is greater than the distance between the gate and the active layer of the other transistors not located above the second electrode 62. In this way, while reducing the layout space of the oxide transistor and improving the resolution, even if the second electrode 62 receives a constant voltage signal causing the threshold voltage of the transistor above it to shift, the greater distance between the gate 5011 and the active layer of the transistor can correspondingly cause its threshold voltage to shift in the opposite direction, and the two offset each other, ensuring the uniformity of the threshold voltages of the transistors and improving the display effect.

Although embodiments of the present disclosure have been described, those skilled in the art will be able to make additional changes and modifications to these embodiments once the basic inventive concepts are apparent. Therefore, it is intended that the appended claims be construed to include embodiments and all changes and modifications that fall within the scope of the disclosure.

Evidently those skilled in the art can make various modifications and variations to the present disclosure without departing from the spirit and scope of the present disclosure. Thus the present disclosure is also intended to encompass these modifications and variations therein as long as these modifications and variations to the present disclosure come into the scope of the claims of the present disclosure and their equivalents.

1. A display substrate, comprising:
a base substrate; and
a plurality of sub-pixels arranged in an array on the base substrate;
wherein each of the sub-pixels comprises a light-emitting device and a pixel driving circuit for driving the light-emitting device, the pixel driving circuit comprises at least two oxide transistors and a storage capacitor;
wherein the storage capacitor includes a first electrode and a second electrode sequentially facing away from the base substrate and arranged opposite to each other;
in the at least two oxide transistors, a distance between a gate of one oxide transistor and an active layer of the one oxide transistor is different from a distance between a gate of at least one of other oxide transistors and an active layer of the at least one of other oxide transistors; and
the one oxide transistor in the at least two oxide transistors with a greater distance between the gate and the active layer is arranged above the second electrode.

2. The display substrate according to claim 1, wherein the second electrode partially overlaps with active layers of the at least two oxide transistors.

3. The display substrate according to claim 2, wherein the pixel driving circuit further comprises at least one polysilicon transistor coupled with the at least two oxide transistors; a gate of the at least one polysilicon transistor is arranged in a same layer as the first electrode, and the at least two oxide transistors are arranged on a side of the second electrode facing away from the base substrate.

4. The display substrate according to claim 3, wherein orthographic projections of the active layers of the at least two oxide transistors on the base substrate completely fall within an orthographic projection of an active layer of the at least one polysilicon transistor on the base substrate.

5. The display substrate according to claim 1, wherein an orthographic projection of the second electrode on the base substrate completely falls within an orthographic projection of the first electrode on the base substrate.

6. The display substrate according to claim 5, wherein the at least two oxide transistors comprise a compensation transistor and a first reset transistor, and the pixel driving circuit further comprises a driving transistor, a first light emitting control transistor, a second light emitting control transistor, a data writing transistor, and a second reset transistor, which are polysilicon transistors; wherein:
the compensation transistor is respectively coupled between a gate of the driving transistor and a first electrode of the driving transistor, and a gate of the compensation transistor is coupled with a first scanning control terminal;
the first reset transistor is respectively coupled between the gate of the driving transistor and an initialization signal terminal, and a gate of the first reset transistor is coupled with the first scanning control terminal;
the storage capacitor is respectively coupled between a first power supply terminal and the gate of the driving transistor;
the first light emitting control transistor is respectively coupled between the first power supply terminal and a second electrode of the driving transistor, and a gate of the first light emitting control transistor is coupled with a light emitting control terminal;
the second light emitting control transistor is respectively coupled between a first electrode of the driving transistor and a first electrode of the light-emitting device, and a gate of the second light emitting control transistor is coupled with the light emitting control terminal;
the data writing transistor is respectively coupled between the second electrode of the driving transistor and a data signal terminal, and a gate of the data writing transistor is coupled with a second scanning control terminal;
the second reset transistor is respectively coupled between the first electrode of the light-emitting device and the initialization signal terminal, and a gate of the second reset transistor is coupled with the second scanning control terminal; and
a second electrode of the light-emitting device is coupled with a second power supply terminal.

7. The display substrate according to claim 6, wherein the compensation transistor and the first reset transistor are both N-type transistors; and the driving transistor, the first light emitting control transistor, the second light emitting control transistor, the data writing transistor and the second reset transistor are all P-type transistors.

8. A display device, comprising:
the display substrate according to claim 1.

9. A method for manufacturing the display substrate according to claim 1, comprising:
forming patterns of the first electrode and the second electrode of the storage capacitor and patterns of active layers of the at least two oxide transistors on the base substrate, sequentially; and
forming a pattern of a gate insulating layer on a side of the active layers of the at least two oxide transistors facing away from the base substrate, so that in the at least two oxide transistors, a distance between a gate and an active layer of one transistor arranged above the second electrode is greater than a distance between a gate and an active layer of other transistors.

10. The manufacturing method according to claim 9, wherein forming the pattern of the gate insulating layer on the side of the active layers of the at least two oxide transistors facing away from the base substrate, comprises:
depositing the gate insulating layer with a first thickness on the side of the active layers of the at least two oxide transistors facing away from the base substrate;
coating a photoresist on the gate insulating layer;
patterning the photoresist by using a composition process, and removing the photoresist at positions corresponding to the other transistors, to form a pattern of the photoresist;
etching the gate insulating layer at the positions corresponding to the other transistor by a third thickness according to the pattern of the photoresist, wherein a difference between the first thickness and the third thickness is a second thickness, and the first thickness is greater than the second thickness; and
removing the pattern of the photoresist to form the pattern of the gate insulating layer.
